(19) United States
(12) Patent Application Publication
(10) Pub. No.: US 2003/0134477 A1
(43) Pub. Date: Jul. 17, 2003

(54) Memory structure and method for manufacturing the same

(76) Inventors: Hung-Sui Lin, Hsin-Ying (TW); Han-Chao Lai, Taichung (TW); Tao-Cheng Lu, Kaoshiung (TW)

Correspondence Address: J.C. Patents, Inc., Suite 250, 4 Venture, Irvine, CA, 92618, US

(21) Appl. No.: 10/055,264

(22) Filed: Jan. 22, 2002

(30) Foreign Application Priority Data
Jan. 11, 2002 (TW) 91100280

(51) Int. Cl. H01L 21/336

(52) U.S. Cl. 438/262

(57) ABSTRACT

The present invention provides a memory structure, comprising: a substrate; a gate structure disposed on the substrate; a buried bit-line disposed in the substrate along both sides of the gate structures; a raised bit-line disposed on the buried bit-line; an isolating spacer disposed on both sidewalls of the gate structure and a word-line disposed over the substrate, wherein the word-line is electrically connected to the gate structure and isolated from the raised bit-line by an insulation layer.

### CROSS-REFERENCE TO RELATED APPLICATION

This application claims the priority benefit of Taiwan application serial no. 91100280, filed Jan. 11, 2002.

### BACKGROUND OF THE INVENTION

1. Field of Invention

The present invention relates to a memory structure and a method for manufacturing the same. More particularly, the present invention relates to a memory structure and a method for manufacturing the same, which can reduce buried bit-line resistance.

2. Description of Related Art

Memory is widely applied in the integrated circuit industry and plays an especially essential role in the electronic industry. For the storage of digital data, the capacitance of the memory is called a “bit” and the unit for data storage in a memory is called a “memory cell”. The memory cells are arranged in an array, consisting of columns and rows. Between a set of columns and rows, the specific position of each memory cell is an address.

FIG. 1 illustrates a cross-sectional view of a prior art memory structure. Referring to FIG. 1, gate structures 108 are formed on a substrate 100. Each gate structure 108 includes a gate conductive layer 104, a gate oxide layer 102. The gate structure 108 can further comprises spacers 110 on sidewalls. Next, buried bit lines 112 are arranged in the substrate 100 along both sides of the gate structure 108. An insulation layer 116 is formed to fill up the space between the gate structures 108 and cover the buried bit-lines 112. Afterwards, word lines 118 are formed over the substrate 100 to connect the gate structures 108.

As the demand for high-density memory increases, the width of the buried bit-lines in memory becomes smaller to satisfy the demand. The smaller the width of the bit line, the higher the resistance, thus reducing the current of the memory cell and inducing higher bit-line loading. However, if the junction depth of the bit-line is increased to improve the aforementioned problems, new issues, including short channel effects and punch-through leakage, can arise. On the other hand, if heavy dosage implantation is used to reduce the resistance, solid solubility limitation may hamper application of heavy dosage implantation for forming shallow junction for the bit-lines.

### SUMMARY OF THE INVENTION

Accordingly, the present invention provides a memory structure and a method for manufacturing the memory structure, which can reduce the resistance of buried bit-lines.

Accordingly, the present invention provides a memory structure and a method for manufacturing the memory structure, which can allow shallow junctions for buried bit-lines, thus preventing short channel effects and punch-through leakage.

As embodied and broadly described herein, the invention provides a memory structure, comprising: a substrate; a gate structure disposed on the substrate; a buried bit-line disposed in the substrate along both sides of the gate structures; a raised bit-line disposed on the buried bit-line; an isolating spacer disposed on both sidewalls of the gate structure, thus isolating the gate structure and the raised bit-line; and a word-line disposed over the substrate, wherein the word-line is electrically connected to the gate structure and isolated from the raised bit-line by an insulation layer. In addition to the raised bit-line made of polysilicon on the buried bit-line, the memory structure of the present invention further includes a metal silicide layer between the raised bit-line and the insulation layer to reduce the resistance of the bit-line.

As embodied and broadly described herein, the invention provides a method for manufacturing a memory structure, comprising: forming a gate structure on a substrate; forming a buried bit-line in the substrate along both sides of the gate structure; forming an isolating spacer on sidewalls of the gate structure after forming the buried bit-line; forming a raised bit-line on the buried bit-line; forming an insulation layer in the raised bit-line; and forming a word-line over the substrate, wherein the word-line is electrically connected to the gate structure and isolated from the raised bit-line by the insulation layer. A metal silicide layer is further formed between the raised bit-line and the insulation layer to reduce the resistance of the bit-line.

As embodied and broadly described herein, the invention provides a method for manufacturing a memory structure, comprising: forming a gate structure on a substrate; forming an isolating spacer on sidewalls of the gate structure; forming a buried bit-line in the substrate along both sides of the isolating spacer of the gate structure; forming a raised bit-line on the buried bit-line; forming an insulation layer in the raised bit-line; and forming a word-line over the substrate, wherein the word-line is electrically connected to the gate structure and isolated from the raised bit-line by the insulation layer. A metal silicide layer is further formed between the raised bit-line and the insulation layer to reduce the resistance of the bit-line.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a cross-sectional view of a prior art memory structure; and

FIGS. 2A to 2H illustrates cross-sectional views of the process steps for forming a memory structure according to one preferred embodiment of this invention; and

FIGS. 3A to 3H illustrates cross-sectional views of the process steps for forming a memory structure according to another preferred embodiment of this invention.

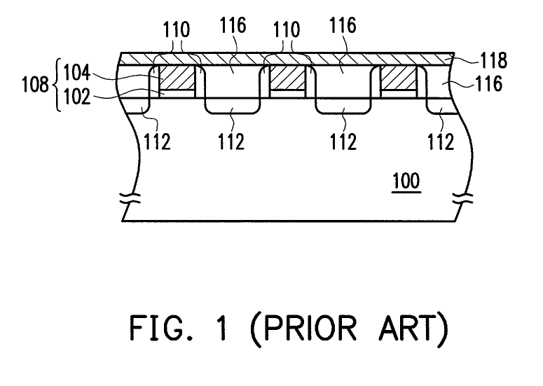

### DESCRIPTION OF THE PREFERRED EMBODIMENTS

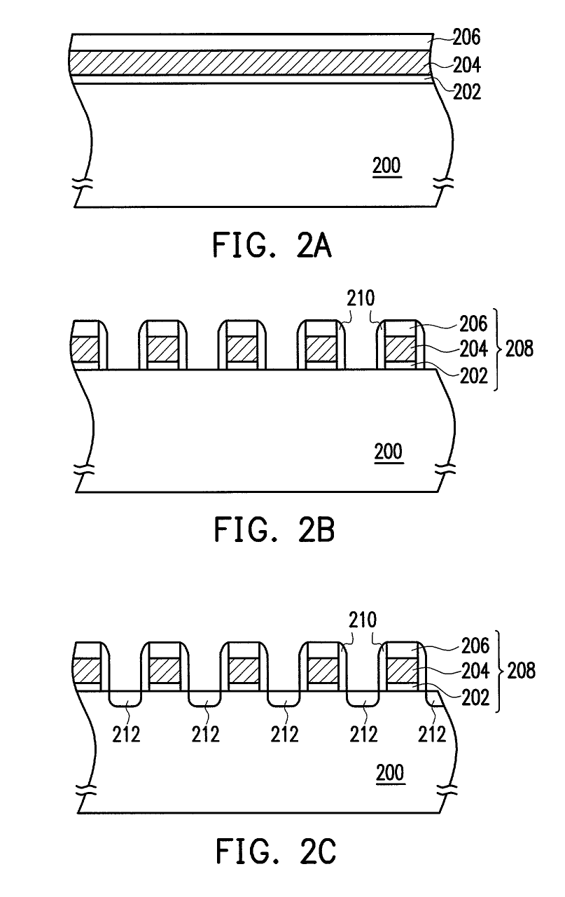

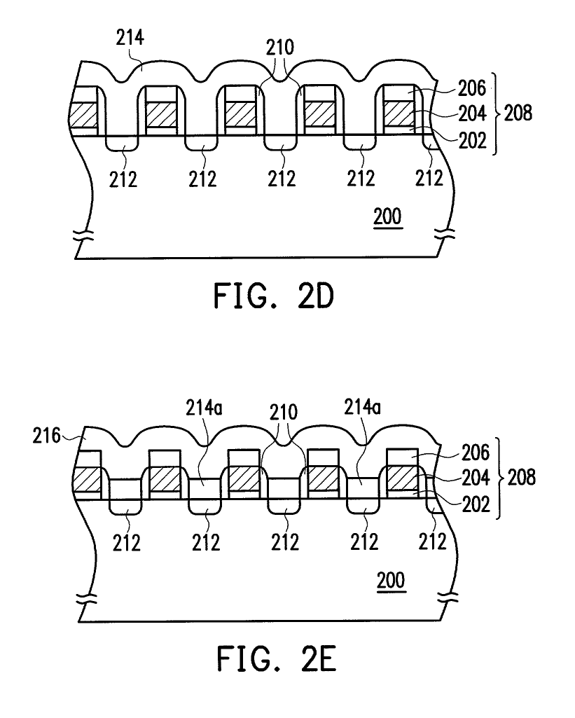

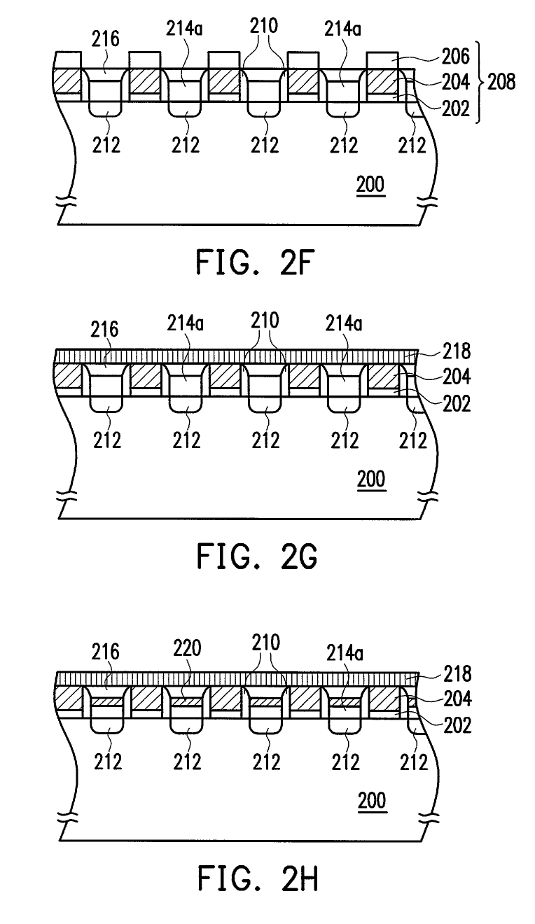

FIGS. 2A to 2H illustrates cross-sectional views of the process steps for forming a memory structure according to one preferred embodiment of this invention.

Referring to FIG. 2A, a gate oxide layer 202, a gate conductive layer 204 and a cap layer 206 are sequentially formed over a provided substrate 200. The material for forming the gate conductive layer 204 includes polysilicon, for example. The cap layer 206 is, for example, a silicon nitride layer.

Referring to FIG. 2B, the gate oxide layer 202, the gate conductive layer 204 and the cap layer 206 are patterned to form a plurality of gate structures 208. Spacers 210 are then formed on sidewalls of the gate structures 208. The method for forming spacers 210 includes, for example, depositing a conformal isolation layer (not shown) and then etching back the isolation layer by dry etching to form spacers.

Referring to FIG. 2C, buried bit-lines 212 are formed in the substrate 200 along both sides of the spacers 210 of the gate structures 208. For example, by using the cap layer 206 and the spacers 210 as a mask, an ion implantation step is performed to form the buried bit-lines 212. If the line-width of the gate structure 208 is about 0.13 micron, the buried bit-line 212 has a junction depth of about 400 to 600 angstroms. If the line-width of the gate structure 208 is about 0.1 micron, the buried bit-line 212 has a junction depth of about 300 to 400 angstroms.

Referring to FIG. 2D, a polysilicon layer 214 is formed over the substrate 200, covering the gate structures 208 and the buried bit-lines 212.

Referring to FIG. 2E, dry etching is performed to the polysilicon layer 214, to remove a portion of the polysilicon layer 214 that is above the gate structures 208. The remained polysilicon layer 214a on the buried bit-lines 212 thus becomes raised bit-lines. Because during the process of etching back the polysilicon layer 214 to form raised bit-lines 214a, the cap layer 206 has an etching rate much slower than that of the polysilicon layer 214, the remained polysilicon layer (i.e. raised bit-lines) 214a is only formed on buried bit-lines 212. After forming the raised bit-lines 214a, an insulation layer 216 is formed over the substrate 200 to cover the gate structures 208 and the raised bit-lines 214a. The insulation layer 216 is made of, for example, silicon oxide formed by chemical vapor deposition.

Referring to FIG. 2F, the insulation layer 216 is etched back until the cap layer 206 is exposed.

Referring to FIG. 2G, after removing the cap layer 206, forming a word-line 218 over the substrate 200. The word-line 218 is electrically connected to the gate conductive layer 204, while the word-line 218 and the raised bit-lines 214a are isolated by the insulation layer 216.

Referring to FIG. 2H, a metal silicide layer 220 is further included between the insulation layer 216 and the raised bit-lines 214a in the memory structure of the present invention, for increasing conductivity of the whole bit-lines. The method for forming the metal silicide layer 220 is, for example, forming a metal layer (not shown) on the raised bit-lines 214a and then performing an annealing process to form metal silicide from reactions between the metal layer and the raised bit-lines 214a.

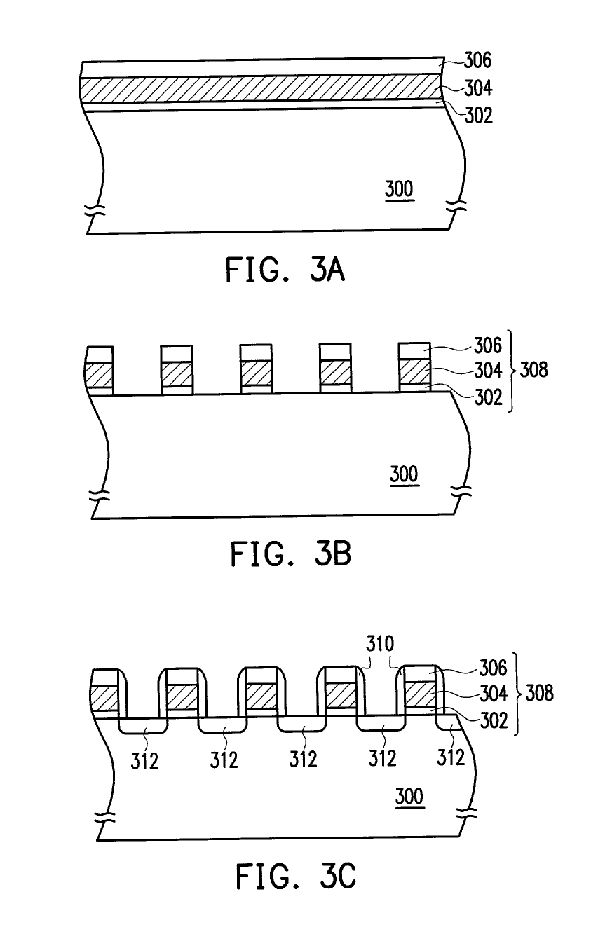

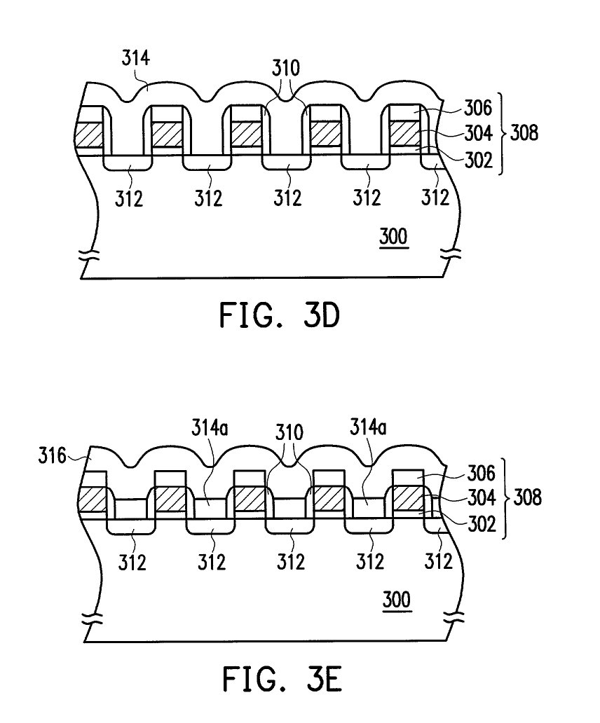

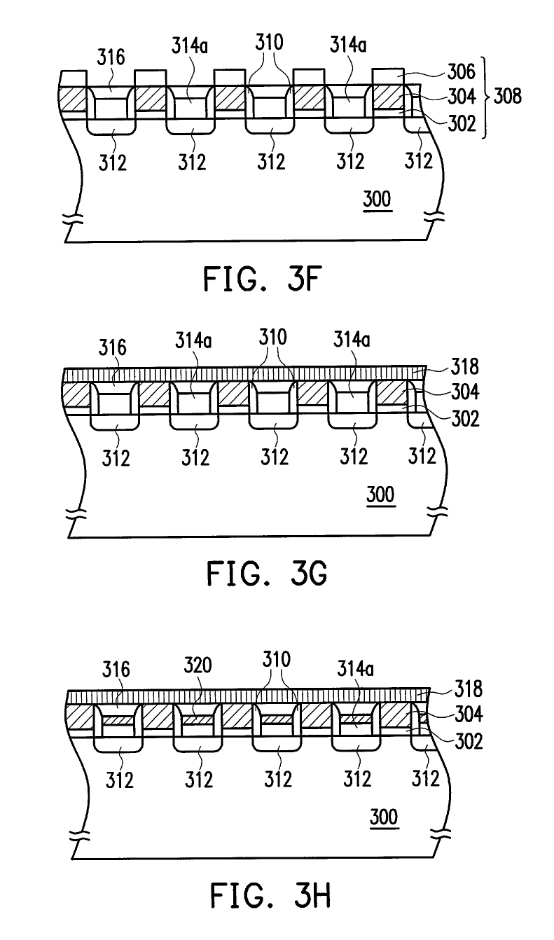

FIGS. 3A to 3H illustrates cross-sectional views of the process steps for forming a memory structure according to another preferred embodiment of this invention.

Referring to FIG. 3A, a gate oxide layer 302, a gate conductive layer 304 and a cap layer 306 are sequentially formed over a provided substrate 300. The material for forming the gate conductive layer 304 includes polysilicon, for example. The cap layer 306 is, for example, a silicon nitride layer.

Referring to FIG. 3B, the gate oxide layer 302, the gate conductive layer 304 and the cap layer 306 are patterned to form a plurality of gate structures 308. Buried bit-lines 312 are formed in the substrate 300 along both sides of the gate structures 308. For example, by using the gate structures 308 as a mask, an ion implantation step is performed to form the buried bit-lines 312. If the line-width of the gate structure 308 is about 0.13 micron, the buried bit-line 312 has a junction depth of about 400 to 600 angstroms. If the line-width of the gate structure 308 is about 0.1 micron, the buried bit-line 312 has a junction depth of about 300 to 400 angstroms.

Referring to FIG. 3C, spacers 310 are then formed on sidewalls of the gate structures 308. The method for forming spacers 310 includes, for example, depositing a conformal isolation layer (not shown) and then etching back the isolation layer by dry etching to form spacers.

Referring to FIG. 3D, a polysilicon layer 314 is formed over the substrate 300, covering the gate structures 308 and the buried bit-lines 312.

Referring to FIG. 3E, dry etching is performed to the polysilicon layer 314, to remove a portion of the polysilicon layer 314 that is above the gate structures 308. The remained polysilicon layer 314a on the buried bit-lines 312 thus becomes raised bit-lines. Because during the process of etching back the polysilicon layer 314 to form raised bit-lines 314a, the cap layer 306 has an etching rate much slower than that of the polysilicon layer 314, the remained polysilicon layer (i.e. raised bit-lines) 314a is only formed on buried bit-lines 312. After forming the raised bit-lines 314a, an insulation layer 316 is formed over the substrate 300 to cover the gate structures 308 and the raised bit-lines 314a. The insulation layer 316 is made of, for example, silicon oxide formed by chemical vapor deposition.

Referring to FIG. 3F, the insulation layer 316 is etched back until the cap layer 306 is exposed.

Referring to FIG. 3G, after removing the cap layer 306, forming a word-line 318 over the substrate 300. The word-line 318 is electrically connected to the gate conductive layer 304, while the word-line 318 and the raised bit-lines 314a are isolated by the insulation layer 316.

Referring to FIG. 3H, a metal silicide layer 320 is further included between the insulation layer 316 and the raised bit-lines 314a in the memory structure of the present invention, for increasing conductivity of the whole bit-lines. The method for forming the metal silicide layer 320 is, for example, forming a metal layer (not shown) on the raised bit-lines 314a and then performing an annealing process to form metal silicide from reactions between the metal layer and the raised bit-lines 314a.

Because the memory of the present invention includes the raised bit-lines 214a, 314a made of polysilicon and metal silicide layers 220, 320 on the buried bit-lines 212, 312, the resistance of the whole bit-line can be effectively reduced. Since the design of the raised bit-lines 214a, 314a made of polysilicon and metal silicide layers 220, 320, the buried bit-lines 212, 312 can adopt shallow junctions, thus avoiding short channel effects and punch-through leakage.

In conclusion, the present invention provide the following advantages:

1. The present invention provides a memory structure and a method for manufacturing the memory structure, which can effectively reduce the resistance of bit-lines and avoid high bit-line loading.

2. The memory structure and the method for manufacturing the memory structure disclosed in the present invention can allow shallow junctions for buried bit-lines, thus preventing short channel effects and punch-through leakage.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A memory structure, comprising:
a substrate;
a gate structure disposed on the substrate;
a buried bit-line disposed in the substrate along both sides of the gate structures;
a raised bit-line disposed on the buried bit-line;
an isolating spacer disposed on both sidewalls of the gate structure, thus isolating the gate structure and the raised bit-line; and
a word-line disposed over the substrate, wherein the word-line is electrically connected to the gate structure and isolated from the raised bit-line by an insulation layer.

2. The structure as claimed in claim 1, wherein a material for forming the raised bit-line comprises polysilicon.

3. The structure as claimed in claim 2, wherein a metal silicide layer is further included between the raised bit-line and the insulation layer.

4. The structure as claimed in claim 1, wherein if a line-width of the gate structure is 0.13 micron, the buried bit-line has a junction depth of 400 to 600 angstroms.

5. The structure as claimed in claim 1, wherein if a line-width of the gate structure is 0.1 micron, the buried bit-line has a junction depth of 300 to 400 angstroms.

6. A method for forming a memory, comprising:
forming a gate structure on a substrate;
forming an isolating spacer on sidewalls of the gate structure;
forming a buried bit-line in the substrate along both sides of the isolating spacer of the gate structure;
forming a raised bit-line on the buried bit-line;
forming an insulation layer on the raised bit-line; and
forming a word-line over the substrate, wherein the word-line is electrically connected to the gate structure and isolated from the raised bit-line by the insulation layer.

7. The method as claimed in claim 6, further includes forming a metal silicide layer between the raised bit-line and the insulation layer.

8. The method as claimed in claim 6, wherein a material for forming the raised bit-line comprises polysilicon.

9. The method as claimed in claim 8, further includes forming a cap layer on the gate structure, and the step of forming the raised bit-line comprises:
forming a polysilicon layer over the substrate to cover the gate structure, the isolating spacer and the buried bit-line; and
etching back the polysilicon layer, thus leaving the remained polysilicon layer on the buried bit-line.

10. The method as claimed in claim 9, wherein the cap layer has an etching rate lower than that of the polysilicon layer.

11. The method as claimed in claim 6, wherein if a line-width of the gate structure is 0.13 micron, the buried bit-line has a junction depth of 400 to 600 angstroms.

12. The method as claimed in claim 6, wherein if a line-width of the gate structure is 0.1 micron, the buried bit-line has a junction depth of 300 to 400 angstroms.

13. A method for forming a memory, comprising:
forming a gate structure on a substrate;
forming a buried bit-line in the substrate along both sides of the gate structure;
forming an isolating spacer on sidewalls of the gate structure after forming the buried bit-line;
forming a raised bit-line on the buried bit-line;
forming an insulation layer in the raised bit-line; and
forming a word-line over the substrate, wherein the word-line is electrically connected to the gate structure and isolated from the raised bit-line by the insulation layer.

14. The method as claimed in claim 13, further includes forming a metal silicide layer between the raised bit-line and the insulation layer.

15. The method as claimed in claim 13, wherein a material for forming the raised bit-line comprises polysilicon.

16. The method as claimed in claim 15, further includes forming a cap layer on the gate structure, and the step of forming the raised bit-line comprises:
forming a polysilicon layer over the substrate to cover the gate structure, the isolating spacer and the buried bit-line; and
etching back the polysilicon layer, thus leaving the remained polysilicon layer on the buried bit-line.

17. The method as claimed in claim 16, wherein the cap layer has an etching rate lower than that of the polysilicon layer.

18. The method as claimed in claim 13, wherein if a line-width of the gate structure is 0.13 micron, the buried bit-line has a junction depth of 400 to 600 angstroms.

19. The method as claimed in claim 13, wherein if a line-width of the gate structure is 0.1 micron, the buried bit-line has a junction depth of 300 to 400 angstroms.
